(19) United States
(12) Patent Application Publication
(10) Pub. No.: US 2022/0263501 A1
(43) Pub. Date: Aug. 18, 2022

(54) DYNAMIC BALANCING OF TRANSISTORS

(71) Applicant: SMARTD TECHNOLOGIES INC., Montréal (CA)

(72) Inventors: Jonathan BRODEUR, St-Jean-sur-Richelieu (CA); Simon CARON, Outremont (CA)

(21) Appl. No.: 17/618,578

(22) PCT Filed: Jun. 1, 2020
(86) PCT No.: PCT/CA2020/050756

§ 371 Date: Dec. 13, 2021

Related U.S. Application Data
(60) Provisional application No. 62/862,384, filed on Jun. 17, 2019.

(51) Int. Cl. H03K 17/082; H03K 17/693

(52) U.S. Cl. CPC H03K 17/0822; H03K 2217/0054; H03K 2217/0027; H03K 17/693

(57) ABSTRACT

The present disclosure provides a cascode switching element comprising two or more electronic switching devices connected in series. The devices having an input terminal, an output terminal, and a control terminal that operates between a closed N state and an open state. The cascode switching element also includes a voltage balancing circuit connected to the at least two electronic switching devices and operative to limit cause the two or more electronic switching devices to share a line voltage across the switching element when in an open state in a manner that a nominal maximum voltage across a first one of the switching devices is not exceeded when said line voltage exceeds said nominal maximum voltage with a remaining portion of said line voltage being present across a remainder of said at least two electronic switching devices.

### CROSS-REFERENCE TO RELATED APPLICATIONS

The present application claims priority from U.S. provisional patent application No. 62/862,384 filed on Jul. 17, 2019, the content of which is incorporated herein by reference.

### TECHNICAL FIELD

The technical field generally relates to electronic switches, and 5 more particularly to serialized transistors for use in electronic contactors and other circuits comprising switching elements.

### BACKGROUND

This section is intended to provide a background or context to the invention that is recited in the claims. The description herein may include concepts that could be pursued but are not necessarily ones that have been previously conceived or pursued. Therefore, unless otherwise indicated herein, what is described in this section is not prior art to the description and claims in this application and is not admitted to be prior art by inclusion in this section.

The emergence of wide-bandgap (WBG) semiconductors such as Gallium Nitride (GaN) and Silicon Carbide (SiC) transistors has enabled novel applications based on their properties of low drain-source on resistance (RDS(on)), fast switching and low switching loss. One potential application is for implementing switching devices which are entirely electronic as opposed to electromechanical. Such an electronic switch could be orders of magnitude faster than its electromechanical counterpart (nanoseconds instead of milliseconds), thus being much safer and more reliable.

Other benefits could include extended endurance, DC compatibility, silent operation and embedded control, among others. Electronic switches are, however, limited by the breakdown voltages of typical transistors. There is therefore a need for improved electronic switching mechanism having WBG benefits while capable of handling high voltages (for example in excess of 600V AC).

### SUMMARY

Applicant has found a method and apparatus for providing WBG switching capable of handling higher voltages than the breakdown voltages of typical transistors.

In according to an aspect, a switching element is provided. The switching element includes at least two electronic switching devices connected in series. Each of the switching devices comprises an input terminal, an output terminal, and a control terminal. The control terminal operates the switching device between a closed state in which current can pass between the input and output terminals, and an open state in which current does not pass between the input and output terminals. A voltage balancing circuit is connected to the at least two electronic switching devices and operative to limit cause the at least two electronic switching devices to share a line voltage across the switching element when in an open state in a manner that a nominal maximum voltage across a first one of the switching devices is not exceeded when the line voltage exceeds the nominal maximum voltage with a remaining portion of the line voltage being present across a remainder of the at least two electronic switching devices.

According to another aspect, the switching element includes: at least two electronic switching devices connected in series, each of said switching devices comprising an input terminal, an output terminal, and a control terminal, said control terminal operating the switching device between a closed state in which current can pass between the input and output terminals, and an open state in which current does not pass between the input and output terminals; and a feedback loop extending between the output terminal of a first one of the switching devices and the control terminal of the second one of the switching devices, the feedback loop operating the second switching device into the off state when the first switching device is also in the off state and a voltage differential across the input and output terminals of the first switching device is above a predetermined threshold.

According to an aspect, a contactor is provided. The contactor includes a plurality of lines, each line including an electronic switching element for establishing and interrupting an electrical connection along the line, said electronic switching element including: at least two electronic switching devices connected in series, each of said switching devices comprising an input terminal, an output terminal, and a control terminal, said control terminal operating the switching device between a closed state in which current can pass between the input and output terminals, and an open state in which current does not pass between the input and output terminals; and a feedback loop extending between the output terminal of a first one of the switching devices and the control terminal of the second one of the switching devices, the feedback loop operating the second switching device into the off state when the first switching device is also in the off state and a voltage differential across the input and output terminals of the first switching device is above a predetermined threshold.

In another broad aspect, the present disclosure provides a switching element. The switch element may comprise at least two electronic switching devices connected in series, each of said switching devices comprising an input terminal, an output terminal, and a control terminal, said control terminal operating the switching device between a closed state in which current can pass between the input and output terminals, and an open state in which current does not pass between the input and output terminals; and a voltage balancing circuit connected to the at least two electronic switching devices and operative to limit cause the at least two electronic switching devices to share a line voltage across the switching element when in an open state in a manner that a nominal maximum voltage across a first one of the switching devices is not exceeded when said line voltage exceeds said nominal maximum voltage with a remaining portion of said line voltage being present across a remainder of said at least two electronic switching devices.

In some embodiments, voltage balancing circuit may be a feedback loop extending between the output terminal of a first one of the switching devices and the control terminal of the second one of the switching devices, the feedback loop operating the second switching device into the off state when the first switching device is also in the off state and a voltage differential across the input and output terminals of the first switching device is above a predetermined threshold.

In some examples of the switching devices may be transistors. In one example the switching devices may be Silicon Carbide (SiC) or Gallium Nitride (GaN) transistors. The transistor type can be a power MOSFET, IGBT, bipolar transistor, thyristor etc. The wide bandgap semiconductor material used can be SiC, GaN or diamond (see the article N Donato et al 2020 J. Phys. D: Appl. Phys. 53 093001 for a description of WBG and ultra WBG materials and their properties and related devices).

In some examples, the feedback loop may comprise a diode element operable to allow a current to pass when a voltage at the output terminal of the first switching device may be above the predetermined threshold.

In some embodiments, the predetermined threshold may be less than or equal to a breakdown voltage of the switching devices.

In some embodiments, the at least two electronic switching devices comprise two groups of at least two electronic switching devices arranged to switch current flowing in either direction across the switching element, and the voltage balancing circuit connected to the at least two electronic switching devices of each one of the two groups.

In one example the control terminal of the first switching device is operatively connected to a microcontroller device. In some embodiment, an electrical circuit may comprise at least one of the switching elements of disclosed herein.

In some examples, the electrical circuit may be a contactor, a soft starter, a motor drive, or a dimmer.

In one example, a contactor comprises a plurality of lines, each line comprising an electronic switching element for establishing and interrupting an electrical connection along the line. The electronic switching element may comprise at least two electronic switching devices connected in series, each of said switching devices comprising an input terminal, an output terminal, and a control terminal, said control terminal operating the switching device between a closed state in which current can pass between the input and output terminals, and an open state in which current does not pass between the input and output terminals; and a feedback loop extending between the output terminal of a first one of the switching devices and the control terminal of the second one of the switching devices, the feedback loop operating the second switching device into the off state when the first switching device is also in the off state and a voltage differential across the input and output terminals of the first switching device is above a predetermined threshold.

In some example of the contactor each line comprises exclusively electronic switching elements and does not comprise electromechanical switching elements.

In some examples, the contactor may further comprise an electromechanical switch positioned on said lines, upstream or downstream from the electronic switching element. In some example of the contactor, the breaking of the lines may be controlled by a microcontroller device.

### BRIEF DESCRIPTION OF THE DRAWINGS

The present examples will be better understood with reference to the appended illustrations which are as follows:

FIG. 1 is a schematic illustration of a circuit diagram of an electronic switch having two twitching devices, according to an embodiment, as part of a leg of a contactor circuit.

FIGS. 2 is a schematic illustration of the electronic switch of FIG. 1 wherein one of the switching devices is off and the voltage applied across line L1 is below the threshold defined by diode element in accordance with one embodiment of the present disclosure.

FIGS. 3 is a schematic illustration of the electronic switch of FIG. 1 wherein both switching devices are off as a result of the voltage applied across line L1 being over the threshold defined by diode element in accordance with one embodiment of the present disclosure.

FIGS. 4 is a schematic illustration of the electronic switch of FIG. 1 wherein both switching devices are off as a result of the voltage applied across line L1 being over the capacity of both transistors accordance with one embodiment of the present disclosure.

FIG. 5 is a circuit diagram illustrating a three-line breaker including electronic switches, according to an embodiment of the present disclosure.

FIG. 6 is a schematic illustration of a circuit diagram of an electronic switch having three switching devices, wherein one of the switches is on and the diodes are in a series setting in accordance with one embodiment of the present disclosure.

FIG. 7 is a schematic illustration of a circuit diagram an electronic switch having three switching devices, wherein one of the switches is on and the diodes are in a parallel setting in accordance with one embodiment of the present disclosure.

FIG. 8 is a schematic illustration of a circuit diagram an electronic switch having two switching devices, wherein a diode connects between two ends of one switching element to allow the exceeding voltage to the other switching element, I accordance to one embodiment of the present disclosure.

### DESCRIPTION

Reference throughout this specification to “one embodiment,” “an embodiment,” or similar language means that a particular feature, structure, or characteristic described in connection with the embodiment is included in at least one embodiment of the present invention. Thus, appearances of the phrases “in one embodiment,” “in an embodiment,” and similar language throughout this specification may, but do not necessarily, all refer to the same embodiment.

Moreover, the described features, structures, or characteristics of the invention may be combined in any suitable manner in one or more embodiments. It will be apparent to those skilled in the art that various modifications and variations can be made to the present invention without departing from the scope of the invention. Thus, it is intended that the present invention cover the modifications and variations of this invention provided they come within the scope of the appended claims and their equivalents. Reference will now be made in detail to the preferred embodiments of the invention.

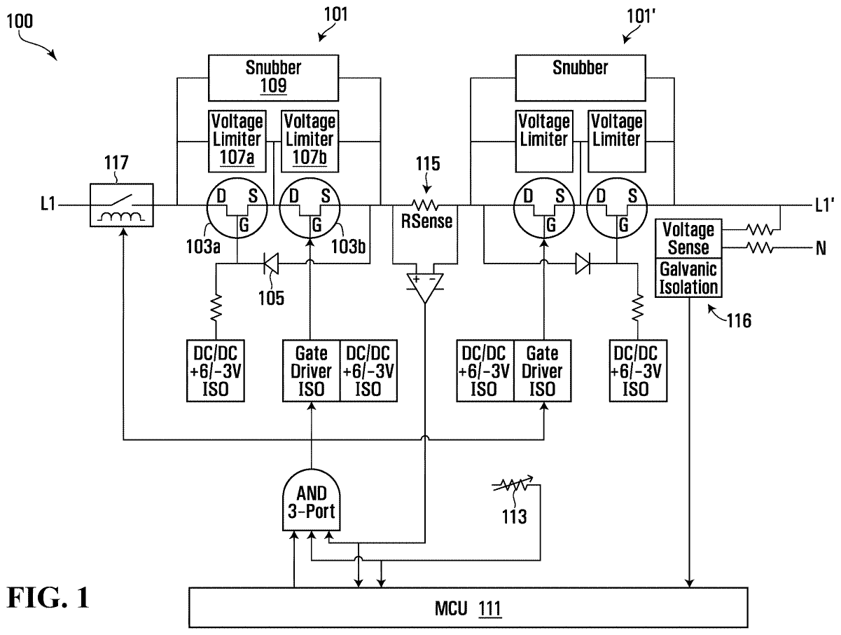

With reference to FIG. 1, an exemplary leg of a contactor circuit 100 is shown according to an embodiment of the present disclosure. The contactor circuit 100 includes an electronic switch 101 which allows for controlling a flow of current between terminals L1, L1′ of circuit 100. More specifically, the circuit 100 is operable in a closed configuration in which current is free to flow between terminals L1, L1′ , and an open configuration in which the flow of current is interrupted. The circuit 100 is further provided with a second switch 101′ in a mirroring configuration relative to the first electronic switch 101, thereby supporting Alternating Current (AC). The configuration of switch 101 will be described below, however it is appreciated that similar configurations will apply to the mirroring switch 101′.

The electronic switch 101 can be implemented, for example, using transistor devices. In the present embodiment, the electronic switch 101 comprises Gallium Nitride (GaN) transistors, although it is appreciated that other types of widebandgap (WBG) transistors can be used, such as Silicon Carbide (SiC) transistors. GaN transistors typically have a breakdown voltage of about 650V, and SiC transistors typically have a breakdown voltage of about 1200V. Under normal circumstances, this would limit the voltage which could be handled by the switch 101. For example, when breaking a 600V AC, a switch would need to withstand a peak voltage of at least 848V (600V* \sqrt{2}). A single GaN transistor would be insufficient, as its breakdown voltage of 650V is well below the peak voltage that it would need to withstand.

To allow handling higher voltages, for example in excess of 650V, the electronics witch 101 comprises a plurality of transistors. For example, in the present embodiment, the switch 101 comprises two GaN transistors 103a, 103b, although it is appreciated that more transistors could be provided as needed. The transistors 103a, 103b are connected in series, allowing the voltage applied to terminal L1 to be distributed between said transistors 103a, 103b, and allowing the switch 101 to have a voltage limit of 1300V.

A load balancer is provided in order to control the distribution of voltage between the transistors 103a, 103b. More specifically, the load balancer is configured such that when a voltage is applied across the switch 101, the voltage is distributed between the transistors 103a, 103b such that neither transistor experiences a voltage exceeding its individual breakdown voltage rating. In some embodiments, the load balancer can be shared evenly. For example, if a 900V voltage is applied across the switch 101, the voltage can be shared equally by both transistors 103a, 103b, such as 450V across the first transistor 103a, and 450V across the second transistor 103b. In this configuration, both transistors 103a, 103b can experience the same voltage, and can each operate well within its rating. If the voltage were to be distributed too unevenly, for example 800V across the first transistor 103a and 100V across the second transistor 103b, the first transistor 103a would exceed its voltage rating and would fail. It is appreciated that in other embodiments, the voltage can be shared differently, so long as neither transistor experiences a voltage exceeding its rating. For example, in some embodiments, a voltage applied across the switch 101 can be borne entirely by one transistor up until a defined threshold. When the applied voltage approaches or exceeds the threshold, the load balancer can cause the additional voltage to be borne by the second transistor (and/or any subsequent transistor) to ensure that the first transistor is not overloaded.

As can be appreciated, if too high a voltage is applied across one of the transistors 103a, 103b even momentarily, the transistor can fail. Accordingly, the load balancer should be configured to balance the voltage dynamically. Moreover, the load balancer should be configured to adequately balance the voltage regardless of production variability and/or die temperature. In the present embodiment, this is achieved at least in part by implementing the load balancer via a load balancing circuit. More specifically, the load balancing circuit comprises a feedback loop between the source of the second GaN transistor 103b and the gate of the first GaN transistor 103a. This feedback loop can allow the ON/OFF state of the first transistor 103a to be set based on the voltage at the source of the second GaN transistor 103b. In this configuration, the first GaN transistor 103a is nominally in an ON state and will be automatically operated into an OFF state if the voltage borne by the second GaN transistor 103b is above a defined threshold. In the present embodiment, the feedback loop comprises a diode element 105 which allows defining the voltage threshold above which the first GaN transistor 103a will be operated into an OFF state. It is appreciated, however, that other configurations are possible. The threshold can be set, for example, at a value less than the breakdown voltage of the GaN transistors 103a, 103b. In some implementations, the threshold can be set to provide a sufficient buffer to prevent the transistors from too closely approaching their breakdown voltage.

Although the load balancing circuit is shown in association with GaN transistors, it is appreciated that a similar circuit can be used to balance other types of transistors, so long as a feedback loop is provided between at least two transistors in series, the feedback loop extending between an output terminal of a first transistor and a control terminal of a second transistor. Moreover, although the balancing circuit is shown in a configuration having two transistors in series, it is appreciated that a similar circuit can be provided for any number n transistors in series.

In addition to the feedback loop described above, it is appreciated that other elements can be provided to further protect the transistors 103a, 103b, and ensure safe and reliable operation of the electronic switch 101. For example, in some embodiments, a snubber element 109 can be provided to help suppress transient voltage oscillation. As another example, in embodiments, a voltage limiter can be provided to ensure energy dissipation if both transistors 103a, 103b are in an OFF state and a current is present. The voltage limiter can be implemented using different technologies, such as a Metal Oxide Varistor (MOV) or a Transient Voltage Suppressor (TVS), among others. In the present embodiment, two voltage limiters are provided in the switch 101, namely a first limiter 107a across the first transistor 103a, and a second limiter 107b across the second transistor 103b, although it is appreciated that in other embodiments, a single voltage limiter can be provided, for example to save on costs. As can be appreciated, the voltage limiter can define a voltage threshold above which current can dissipate therethrough, thus defining a maximum voltage which can be applied across the transistors 103a, 103b. To protect the transistors 103a, 103b, the voltage threshold can be set to be below the breakdown voltages of transistors 103a, 103b. In embodiments where a single voltage limiter is provided, the limiter can set a threshold being below a sum total of the breakdown voltages of all the transistors in series in the switch 101. In some embodiments, the threshold can be set to provide a sufficient buffer to prevent transistors from approaching their breakdown voltages too closely.

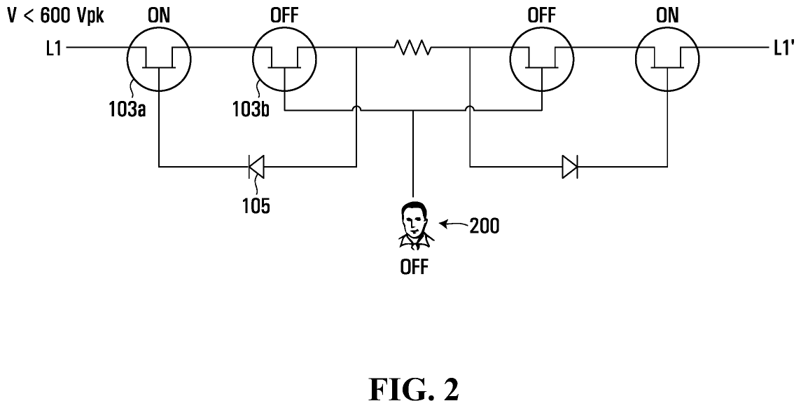

With reference to the schematics of FIGS. 2, 3 and 4, operation of the electronic switch 101 will now be described under different scenarios. For illustrative purposes, the diode element 105 is configured at 600V (i.e. below the 650V breakdown voltage of the transistors), and the voltage limiter is configured to set the maximum breaking voltage 1200V (i.e. below the combined 1300V breakdown voltage of both transistors), but it is appreciated that other configurations of diode 105 are possible.

For example, although it is preferred that switch 103b is controlled to be off by the control signal, while switch 103a is gated using the feedback through diode 105, it would be possible to have the control signal gate 103a with the diode 105 arranged to gate transistor 103b when the voltage across 103a exceeds the desired threshold. In this case the feedback loop is arranged to feedforward the gate signal. Such an alternative may have the problem that the leakage current through switch 103a may be insufficient to keep the voltage across 103a within tolerances as the voltage drop develops across switch 103b, and thus lead to failure of switch 103a.

Likewise, while a diode is shown as a single device, it will be appreciated that it can be an arrangement of Zener diodes to provide the desired breakdown voltage. Alternatively, other circuits can be used to provide the feedback signal once the voltage exceeds a threshold, such as a suitable comparator circuit. Such an alternative may have the problem that the response time of a more complex comparator circuit may be insufficient to keep the voltage across 103b within tolerances as the voltage drop develops across switch 103a, and thus lead to failure of switch 103b.

In the illustrated scenarios, a user 200 issues a command to break (i.e. open) line L1, for example via a controller or other device, thereby causing one or both of the transistors 103a, 103b to operate into an OFF state and bear a voltage V applied across line L1. It is appreciated that when the user 200 does not issue a break command, both transistors 103a, 103b are in an ON state, thereby maintaining a closed circuit and allowing current to flow freely without a significant voltage differential across transistors 103a, 103b.

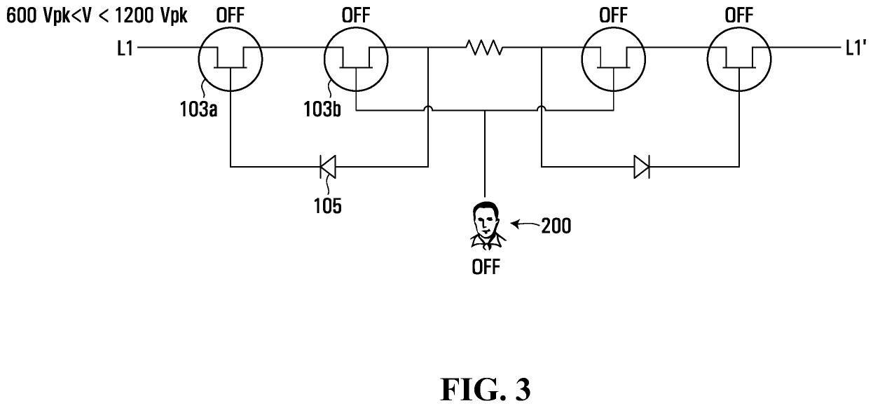

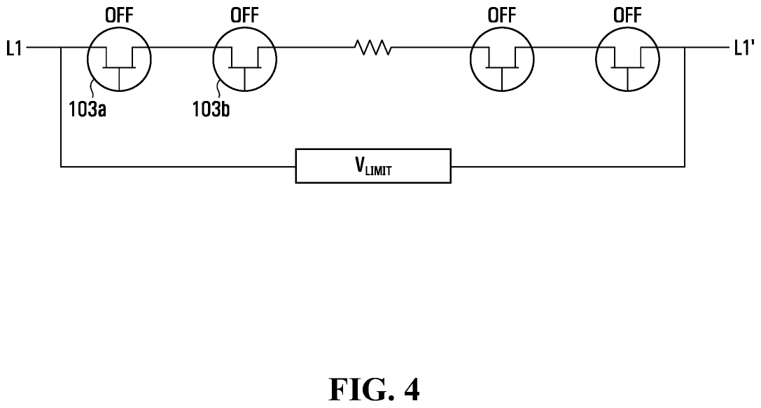

As shown in FIG. 2, when user 200 issues a break command (i.e. by providing an OFF-control signal), the second transistor 103b is operated into an OFF state via a gate driver, thereby creating an open circuit along line L1. When the voltage V applied across line L1 is below 600V (i.e. the threshold defined by diode element 105), the first transistor 103a remains in its nominal ON state, thus causing the voltage V to be borne only by second transistor 103b. As shown in FIG. 3, as the voltage V is increased above the threshold of 600V, the diode element 105 will activate and operate the first transistor 103a into an OFF state. Accordingly, any voltage in excess of 600V will be borne by the first transistor 103a, thereby protecting the second transistor 103b which will continue to bear a maximum of 600V. This operation can continue as the voltage V is increased up until 1200V (i.e. the threshold defined by the voltage limiter). As shown in FIG. 4, once the voltage V reaches 1200V, the voltage limiter will limit the differential across the transistors to 1200V, for example by allowing a small current to pass therethrough. This can protect the transistors 103a, 103b from excess voltage, but the switch 101 will have exceeded its maximum effective breaking capacity.

In the provided example, operation of switch 101 is described as being commanded by a user 200. It is appreciated that user 200 can refer to any electronic or electromechanical device capable of sending a control signal to switch 101. For example, and referring back to FIG. 1, the user 200 can correspond to a controller, such as a microcontroller device 111, capable of sending a digital ON/OFF control signal to switch. It is appreciated that the microcontroller device 111 can be programmed to operate the switch between ON/OFF states as required, for example at different frequencies or intervals. It is further appreciated that control of switch 101 can take into account control signals from other sources as well. For example, sensors can be provided to monitor the switching circuit and/or its environment and turn the switch on or off as needed. In the present embodiment, a thermal sensor 113 is provided to monitor ambient temperature, and a current sensor 115 is provided to measure the current flowing through line L1. The sensors are configured such that a current and/or temperature above a determined threshold will cause the switch 101 to open, for example to prevent damage thereto. Accordingly, in the present configuration, the following conditions must be met to close the switch 101: (1) the microcontroller 111 must issue a command to close the switch 101; (2) the current must be below a predetermined threshold; and (3) the temperature must be below a predetermined threshold. It is appreciated that in other embodiments, other sensors can be provided (such as one or more voltage sensors 116), and other parameters can be taken into account when controlling the switch 101.

As can be appreciated, the electronic switch 101 can be used for a variety of different applications. In the present embodiment, and as described above, the switch 101 is used as part of electronic contactor 100. In other embodiments, the electronic switch 101 can be used as part of other types of circuits requiring switching components, such as a soft starter, a motor drive, or a dimmer, among others. In some embodiments, the switch 101 can be provided as the only switching component in the circuit. For example, in the case of a contactor or breaker, this can allow fora contactor or breaker which is completely electronic.

However, it is appreciated that in other embodiments, other switching components can also be provided as needed. For example, in the present embodiment a mechanical actuator 117 is provided along line L1, upstream from the switch 101. The mechanical actuator 117 is also commanded by the microcontroller 111 and can allow for physical switching/breaking of the circuit if needed. It is appreciated, however, that other configurations are also possible. For example, in some embodiments a mechanical actuator can additionally or alternatively be provided downstream from the switch 101.

It will be appreciated by those skilled in the art that microcontroller device may use different techniques know in the art for switching such as pulse width modulation (PWM), Binary Code Modulation (BCM), Pulse-code modulation (PCM), Linear pulse-code modulation (LPCM).

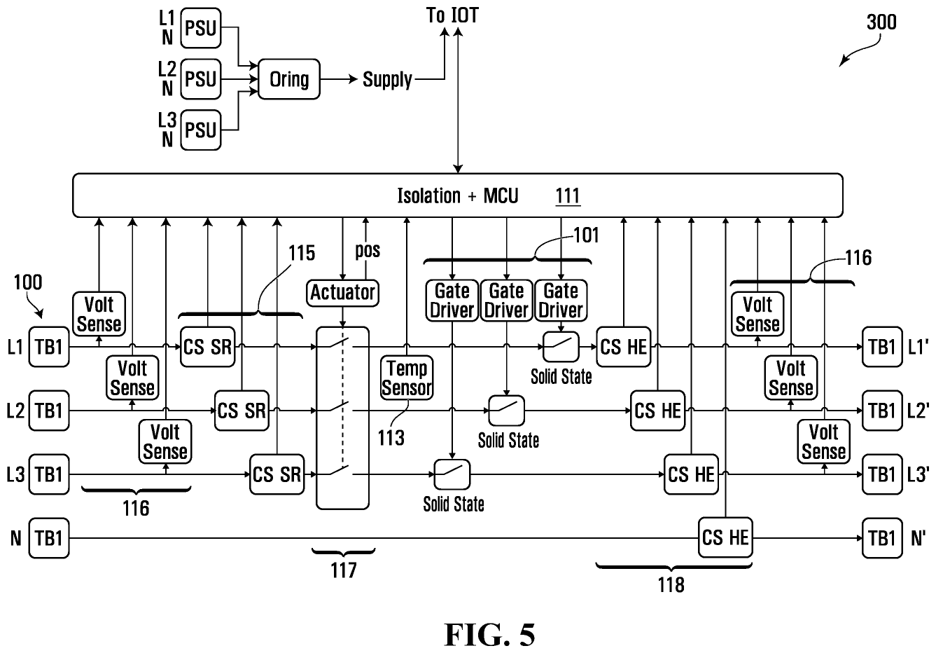

In the above-described exemplary embodiments, a single line L1 of a contactor circuit is shown. It is appreciated, however, that a plurality of similarly configured lines can be provided as needed. For example, with reference to FIG. 5, an exemplary three-line circuit breaker 300 is shown according to an embodiment. The circuit breaker 300 includes three lines L1, L2 and L3, although it is appreciated that more or fewer lines can be provided in other embodiments. Each line includes a contactor circuit 100 similar to the one described above, comprising an electronic switch 101, a mechanical actuator 117, a thermal sensor 113, a current sensor 115, voltage sensors 116, and further including a hall effect current sensor 118. Operation of the breaking elements on the three lines L1, L2, and L3 is commanded by a microcontroller 111.

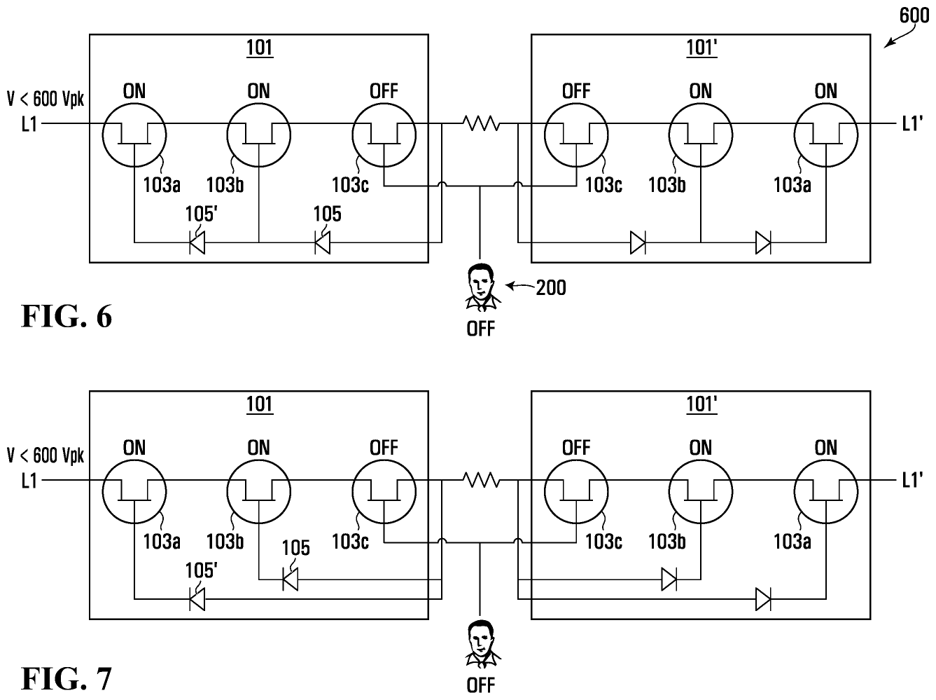

Referring now FIG. 6, an embodiment of the present disclosure has been illustrated wherein the switch 101 may have three transistors 103a, 103b and 103c.

Similar to other embodiments the circuit 300 may further comprise a second switch 101′ in a mirroring configuration relative to the first electronic switch 101, thereby supporting Alternating Current (AC).

It will be appreciated that while it has been illustrated as to mirror switch 101, the second switch 101′, in some embodiments, may have a different structure providing the same purpose as switch 101.

It will be appreciated by those skilled in the that the configuration of the configuration as well as the manner of functionality may be similar between switch 101 and switch 101′.

As shown in FIG. 6, when user 200 issues a break command (i.e. by providing an OFF-control signal), the third transistor 103c is operated into an OFF state via a gate driver, thereby creating an open circuit along line L1. When the voltage V applied across line L1 is below 600V (i.e. the threshold defined by diode element 105), the first two transistors 103a and 103b may remain in their nominal ON state, thus causing the voltage V to be borne only by second transistor 103c.

As the voltage V is increased above the threshold set, 600V in this example, the diode element 105 will activate and operate the first transistor 103b into an OFF state. Accordingly, any voltage in excess of 600V will be borne by the first transistor 103b, thereby protecting the second transistor 103c which will continue to bear a maximum of 600V. when the voltage increase even over 1200 (or the threshold of transistor 103b and 103c), the diode element 105′ will activate and operate the first transistor 103a into an OFF state. This operation can continue as the voltage V is increased up until the threshold defined by the voltage limiter and as many transistors as required may be added.

As mentioned before, in some embodiments, once the voltage V reaches 1800V, the voltage limiter may limit the differential across the transistors to 1800V, for example by allowing a small current to pass therethrough. This can protect the transistors 103a, 103b, and 103c from excess voltage, but the switch 101 will have exceeded its maximum effective breaking capacity.

In some embodiments, as illustrated in FIG. 7, the feedback loop for transistor 1031 and 103b, for example diode element 105 and 105′, may have a parallel setting allowing the extra voltage of 103 to result in activation one or both of the transistors 103b and 103c depending on the setting of the thresholds and other factors known in the art.

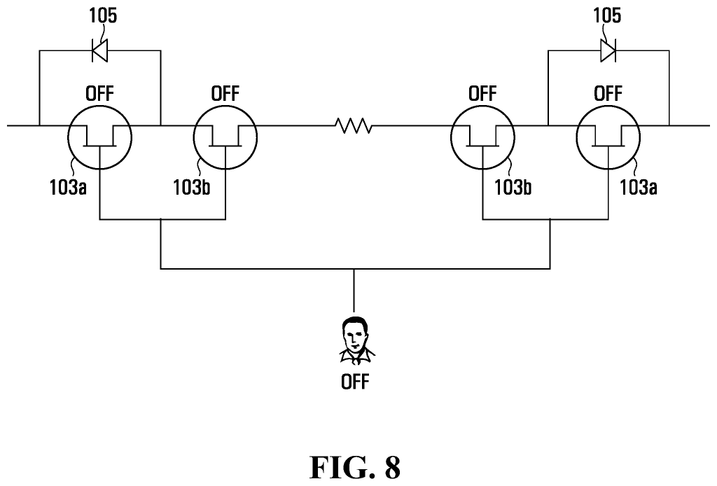

As illustrated in FIG. 8, in some embodiments, the diode element may connect to the two ends of the transistor 103a. When user 200 issues a break command, both transistor 103a and 103b is operated into an OFF state via a gate driver, thereby creating an open circuit along line L1. When the voltage exceeds the threshold defined by diode element 105, it allows the voltage and results both transistors 103a and 103b to mutually borne the voltage across L1.

In the foregoing specification, specific embodiments have been described. However, one of ordinary skill in the art appreciates that various modifications and changes can be made without departing from the scope of the invention. Accordingly, the specification and figures are to be regarded in an illustrative rather than a restrictive sense, and all such modifications are intended to be included within the scope of present teachings.

1. A switching element, comprising:
at least two electronic switching devices connected in series, each of said switching devices comprising an input terminal, an output terminal, and a control terminal, said control terminal operating the switching device between a closed state in which current can pass between the input and output terminals, and an open state in which current does not pass between the input and output terminals; and
a voltage balancing circuit connected to the at least two electronic switching devices and operative to limit cause the at least two electronic switching devices to share a line voltage across the switching element when in an open state in a manner that a nominal maximum voltage across a first one of the switching devices is not exceeded when said line voltage exceeds said nominal maximum voltage with a remaining portion of said line voltage being present across a remainder of said at least two electronic switching devices.

2. The switching element as defined in claim 1, wherein said voltage balancing circuit is a feedback loop extending between the output terminal of a first one of the switching devices and the control terminal of the second one of the switching devices, the feedback loop operating the second switching device into the off state when the first switching device is also in the off state and a voltage differential across the input and output terminals of the first switching device is above a predetermined threshold less than or equal to a breakdown voltage of the switching devices.

3. The switching element according to claim 1, wherein one of the at least two electronic switching devices are Silicon Carbide (SiC) transistors.

4. The switching element according to claim 1, wherein one of the at least two electronic switching devices are Gallium Nitride (GaN) transistors.

5. The switching element according to claim 2, wherein the feedback loop comprises a diode element operable to allow a current to pass when a voltage at the output terminal of the first switching device is above the predetermined threshold.

6. The switching element according to claim 1, wherein said at least two electronic switching devices comprise two groups of at least two electronic switching devices arranged to switch current flowing in either direction across said switching element, and said voltage balancing circuit connected to the at least two electronic switching devices of each one of said two groups.

7. The switching element according to claim 1, further comprising a microcontroller device, wherein the control terminal of the first switching device is operatively connected to the microcontroller device.

8. The switching element according to claim 7, further comprising a mechanical actuator controlled by said microcontroller.

9. The switching element according to claim 7, wherein the microcontroller device uses Pulse Width Modulation (PWM) to control the electronic switching devices.

10. The switching element according to claim 1, further comprising a snubber element reducing transient voltage oscillation.

11. The switching element according to claim 1, further comprising at least one voltage limiter connected to said at least two electronic switching devices.

12. An electrical circuit comprising the switching elements of claim 1.

13. The electrical circuit according to claim 12, wherein the electrical circuit is a contactor for a plurality of lines.

14. The electrical circuit according to claim 13, comprising a microcontroller device, wherein the microcontroller device is operatively coupled to sensors configured to monitor the contactor circuit and/or its environment, wherein breaking of the lines is controlled by a microcontroller device.

15. The electrical circuit according to claim 13, wherein each line comprises exclusively electronic switching elements.

16. The electrical circuit according to claim 13, further comprising an electromechanical switch positioned on said lines, upstream or downstream from the electronic switching element.

17. The electrical circuit according to claim 14, wherein the sensors comprise a voltage sensor and a current sensor.

18. The electrical circuit according to claim 14, wherein the sensors comprise a temperature sensor, and a hall effect current sensor.

19. The electrical circuit according to claim 12, wherein the electrical circuit is a soft starter, a motor drive, or a dimmer.
